(19) United States
(12) Patent Application Publication
(10) Pub. No.: US 2011/0279168 A1
(43) Pub. Date: Nov. 17, 2011

(54) TEMPERATURE SENSOR

(75) Inventors: Seong Seop LEE, Icheon-si (KR); Saeng Hwan KIM, Suwon-si (KR)

(73) Assignee: HYNIX SEMICONDUCTOR INC., Icheon-si (KR)

(21) Appl. No.: 12/947,141

(22) Filed: Nov. 16, 2010

(30) Foreign Application Priority Data
Feb. 25, 2010 (KR) 10-2009-0017333

(51) Int. Cl. H03K 3/011

(52) U.S. Cl. 327/512

(57) ABSTRACT

A temperature sensor includes a selection signal generation unit and a reference voltage selection unit. The selection signal generation unit is configured to generate first and second selection signals in response to a fuse cutting or an input of a test mode pulse in a test mode. The reference voltage selection unit is configured to output a first reference voltage or a second reference voltage as a first selection reference voltage, and output a third reference voltage or a fourth reference voltage as a second selection reference voltage in response to the first and second selection signals.

### CROSS-REFERENCES TO RELATED APPLICATIONS

The present application claims priority under 35 U.S.C 119(a) to Korean application number 10-2010-0017333, filed on Feb. 25, 2010, in the Korean intellectual property Office, which is incorporated herein by reference in its entirety set forth in full.

### BACKGROUND

To meet the demands of the high performance of electronic systems such as personal computers or electronic communication devices, nonvolatile semiconductor memory devices such as DRAMs mounted as memory devices have been designed to operate at higher speed and have become highly integrated. Since semiconductor memory devices mounted on battery-driven systems such as mobile phones or notebook computers desperately require a low power consumption characteristic, many efforts and developments have been made to reduce an operating current and a standby current.

A data retention characteristic of a DRAM cell consisting of one transistor and one storage capacitor is very sensitive to temperature. Therefore, it may be necessary to adjust the operating conditions of circuit blocks inside semiconductor integrated circuits, depending on the variation in an ambient temperature. For example, DRAMs used in mobile products adjust a refresh period, depending on the variation in an ambient temperature. Temperature sensors, such as a Digital Temperature Sensor Regulator (DTSR), an Analog Temp Sensor Regulator (ATSR), and a Digital Temperature Compensated Self Refresh (DTCSR), are used to adjust the operating conditions depending on the variation in the ambient temperature.

FIG. 1 is a block diagram illustrating the configuration of a conventional temperature sensor.

As illustrated in FIG. 1, the conventional temperature sensor includes a sense voltage generation unit 10 and a temperature code generation unit 11. The sense voltage generation unit 10 is configured to sense an inside temperature of a semiconductor integrated circuit and generate a sense voltage VSENSE. The temperature code generation unit 11 is configured to compare the level of the sense voltage VSENSE with the level of a reference voltage VREF and generate a temperature code TQ. The temperature sensor configured as above compares the level of the sense voltage VSENSE with the level of the reference voltage VREF and generates the temperature code TQ containing information on whether the inside temperature of the semiconductor integrated circuit is higher than temperature corresponding to the level of the reference voltage VREF.

However, since such a temperature sensor can sense only one temperature, it is necessary to adjust the level of the reference voltage VREF through a design modification in order to sense a plurality of temperatures. Furthermore, when the level of the sense voltage VSENSE changes according to process variations, a design modification for adjusting the level of the reference voltage VREF is required.

### SUMMARY

An embodiment of the present invention relates to a temperature sensor which is capable of easily sensing a plurality of temperatures, without design modification, and coping with process variations.

In one embodiment, a temperature sensor includes: a selection signal generation unit configured to generate first and second selection signals in response to a fuse cutting or an input of a test mode pulse in a test mode; and a reference voltage selection unit, operatively coupled to the selection signal generation unit, configured to output a first reference voltage or a second reference voltage as a first selection reference voltage, and output a third reference voltage or a fourth reference voltage as a second selection reference voltage in response to the first and second selection signals.

In another embodiment, a temperature sensor includes: a sense voltage generation unit configured to sense an inside temperature of a semiconductor integrated circuit and generate a sense voltage; a selection signal generation unit configured to generate a selection signal in response to a fuse cutting or an input of a test mode pulse in a test mode; a reference voltage selection unit, operatively coupled to the selection signal generation unit, configured to selectively output first and second selection reference voltages among a plurality of reference voltages in response to the selection signal; a first comparator, operatively coupled to the sense voltage generation unit and the reference voltage selection unit, configured to compare the first selection reference voltage with the sense voltage, and generate a first flag signal; and a second comparator, operatively coupled to the sense voltage generation unit and the reference voltage selection unit, configured to compare the second selection reference voltage with the sense voltage, and generate a second flag signal.

### BRIEF DESCRIPTION OF THE DRAWINGS

The above and other aspects, features and other advantages will be more clearly understood from the following detailed description taken in conjunction with the accompanying drawings, in which:

FIG. 1 is a block diagram illustrating the configuration of a conventional temperature sensor;

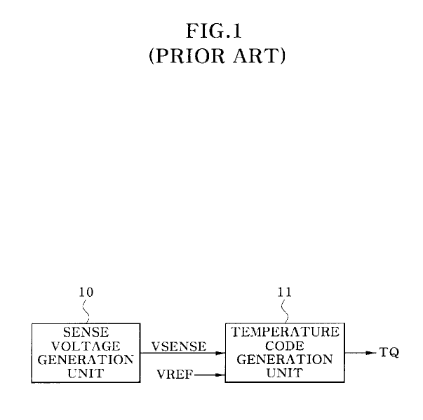

FIG. 2 is a circuit diagram illustrating the configuration of a temperature sensor according to an embodiment of the present invention;

FIG. 3 is a circuit diagram of a selection signal generation unit included in the temperature sensor of FIG. 2;

FIG. 4 is a circuit diagram of a reference voltage selection unit included in the temperature sensor of FIG. 2; and

FIG. 5 is a graph explaining the operation of the temperature sensor of FIG. 2 when the level of a sense voltage changes according to process variations.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

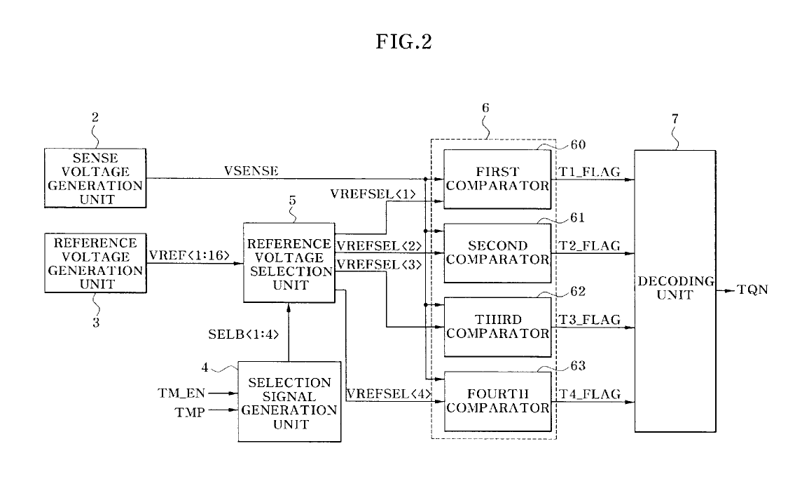

FIG. 2 is a block diagram illustrating the configuration of a temperature sensor according to an embodiment of the present invention.

Referring to FIG. 2, the temperature sensor according to the embodiment includes a sense voltage generation unit 2, a reference voltage generation unit 3, a selection signal generation unit 4, a reference voltage selection unit 5, a comparison unit 6, and a decoding unit 7. The sense voltage generation unit 2 is operatively coupled to the comparison unit 6. The terminology “operatively coupled” as used herein refers to coupling that enables operational and/or functional communication and relationships there-between and may include any intervening items necessary to enable such communication such as, for example, data communication buses or any other necessary intervening items that one of ordinary skill would understand to be present. Also, it is to be understood that other intervening items may be present between “operatively coupled” items even though such other intervening items are not necessary to the functional communication facilitated by the operative coupling. For example, a data communication bus may provide data to several items along a pathway along which two or more items are operatively coupled, etc. Such operative coupling is shown generally in the figures described herein. Therefore, as shown in FIG. 2, the reference voltage generation unit 3 is operatively coupled to the reference voltage selection unit 5. The reference voltage selection unit 5 is operatively coupled to the selection signal generation unit 4 and to the comparison unit 6. The comparison unit 6 is coupled to the decoding unit 7.

The sense voltage generation unit 2 is configured to sense an inside temperature of a semiconductor integrated circuit and generate a sense voltage VSENSE, which it provides as an input to the comparison unit 6. The sense voltage generation unit 2 may be implemented in some embodiments using a resistor or a MOS transistor which has a different current drivability, depending on the inside temperature of the semiconductor integrated circuit.

The reference voltage generation unit 3 includes a plurality of resistors and is configured to divide a power supply voltage (VDD) or an internal voltage and generate first to sixteenth reference voltages VREF<1:16> having levels corresponding to the inside temperature of the semiconductor integrated circuit. In this embodiment, the sixteenth reference voltage VREF<16> is generated to have the highest level so that it corresponds to the lowest inside temperature of the semiconductor integrated circuit. The first reference voltage VREF<1> is generated to have the lowest level so that it corresponds to the highest inside temperature of the semiconductor integrated circuit.

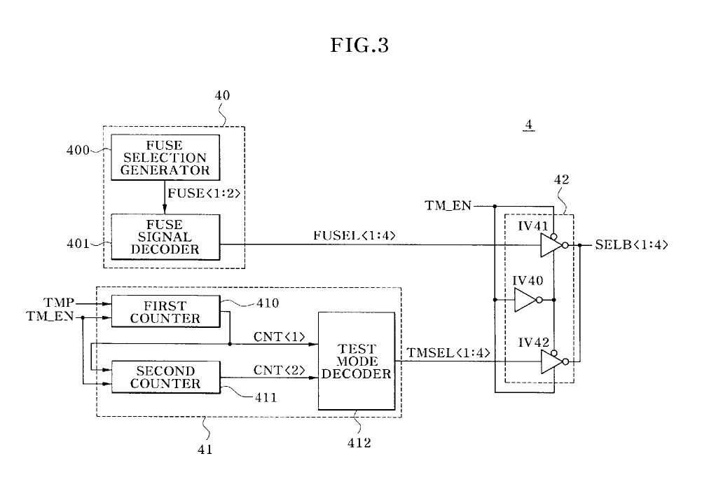

As illustrated in FIG. 3, the selection signal generation unit 4 includes a fuse selection signal generation section 40, a test mode to selection signal generation section 41, and a selective transfer section 42. The fuse selection signal generation section 40 and the test mode selection signal generation section 41 are both operatively coupled to the selective transfer section 42.

The fuse selection signal generation section 40 includes a fuse selection generator 400 and a fuse signal decoder 401. The fuse selection generator 400 is operatively coupled to the fuse signal decoder 401 and is configured to generate first and second fuse signals FUSE<1:2> according to, and, in response to, whether first and second fuses (not shown) are cut or not. The fuse signal decoder 401 is operatively coupled to the selective transfer section 42 and is configured to decode the first and second fuse signals FUSE<1:2> and generate first to fourth fuse selection signals FUSEL<1:4> which it provides as input to the selective transfer section 42. The first fuse signal FUSE<1> has a logic low level when the first fuse (not shown) is not cut, and has a logic high level when the first fuse (not shown) is cut. Logic “high level” and “low level” refers to, for example, voltage levels and/or voltage ranges that are predetermined to represent the high level or low level and not necessarily any specific values. It is to be understood that “high level” and “low level” may also be referred to as “logic levels” for example, a “logic high level” and a “logic low level,” respectively. Such “logic levels” may also be understood to correspond to logical or binary bit values, for example, where a “logic low level” corresponds to a logical “0” and a “logic high level” corresponds to a logical “1,” or vice versa depending on specific implementations in the various embodiments. Therefore, turning again to FIG. 3, the second fuse signal FUSE<2> has a logic low level when the second fuse (not shown) is not cut, and has a logic high level when the second fuse (not shown) is cut. The fuse selection signal generation section 40 configured as above generates the first to fourth fuse selection signals FUSEL<1:4> which are enabled to a logic high level according to whether the first and second fuses (not shown) are cut. For example, as shown in Table 1 below, only the first fuse selection signal FUSEL<1> is enabled to a logic high level when both of the first and the second fuses (not shown) are not cut, and only the third fuse selection signal FUSEL<3> is enabled to a logic high level when only the second fuse (not shown) is cut.

TABLE 1

| FUSE | FUSE | FUSEL | FUSEL | FUSEL | FUSEL |
|---|---|---|---|---|---|
| <2> | <1> | <4> | <3> | <2> | <1> |
| L | L | L | L | L | H |
| L | H | L | L | H | L |
| H | L | L | H | L | L |
| H | H | H | L | L | L |

Referring to FIG. 3, the test mode selection signal generation section 41 includes a first counter 410, a second counter 411, and a test mode decoder 412. The first counter 410 is operatively coupled to the second counter 411 and to the test mode decoder 412, and is driven when a test mode signal TM_EN is enabled to a logic high level in a test mode. In the test mode, the first counter 410 counts a first counting signal CNT<1> whenever a test mode pulse TMP is inputted. The second counter 411 is operatively coupled to the test mode decoder 412 and is driven when the test mode signal TM_EN is enabled to a logic high level in the test mode, and counts a second counting signal CNT<2> whenever the first counting signal CNT<1> is inputted. The test mode decoder 412 is operatively coupled to the selective transfer section 42 and decodes the first counting signal CNT<1> and the second counting signal CNT<2> and generates first to fourth test mode selection signals TMSEL<1:4>. When the test mode signal TM_EN is enabled to a logic high level, the test mode selection signal generation section 41 configured as above generates the first to fourth test mode selection signals TMSEL<1:4> which are selectively enabled to a logic high level whenever the first mode pulse TMP is inputted. For example, as shown in Table 2 below, only the test mode selection signal TMSEL<2> is enabled to a logic high level when the test mode pulse TMP is inputted one time, and only the fourth test mode selection signal TMSEL<4> is enabled to a logic high level when the test mode pulse TMP is inputted three times.

TABLE 2

| TMP | CNT<2> | CNT<1> | TMSEL<4> | TMSEL<3> | TMSEL<2> | TMSEL<1> |
|---|---|---|---|---|---|---|
| Default | L | L | L | L | L | H |
| 1 | L | H | L | L | H | L |
| 2 | H | L | L | H | L | L |
| 3 | H | H | H | L | L | L |

The selective transfer section 42 includes an inverter IV41 and IV42. The inverter IV41, is operatively coupled to the fuse signal decoder 401 and is turned on in response to the test mode signal TM_EN which is disabled to a logic low level in modes other than the test mode, and buffers the first to fourth fuse selection signals FUSEL<1:4> to output first to fourth selection signals SELB<1:4>. The inverter IV42 is operatively coupled to the test mode decoder 412 and is turned on in response to the test mode signal TM_EN which is enabled to a logic high level in the test mode, and buffers the first to fourth test mode selection signals TMSEL<1:4> to output the first to fourth selection signals SELB<1:4>.

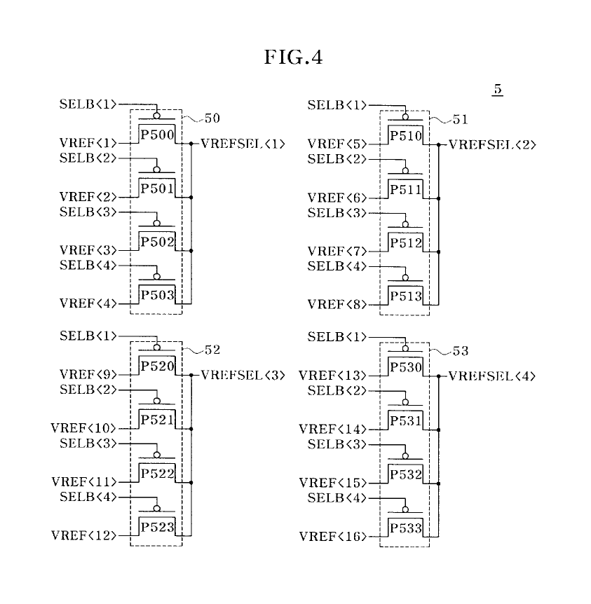

As illustrated in FIG. 4, the reference voltage selection unit 5 includes a first reference voltage selection section 50, a second reference voltage selection section 51, a third reference voltage selection section 52, and a fourth reference voltage selection section 53.

Referring to FIG. 4, the first reference voltage selection section 50 includes a PMOS transistor P500, a PMOS transistor P501, a PMOS transistor P502, and a PMOS transistor P503. Specifically, the PMOS transistor P500 operates as a switch which is turned on when the first selection signal SELB<1> is enabled to a logic low level, and transfers the first reference voltage VREF<1> as a first selection reference voltage VREFSEL<1>. The PMOS transistor P501 operates as a switch which is turned on when the second selection signal SELB<2> is enabled to a logic low level, and transfers the second reference voltage VREF<2> as the first selection reference voltage VREFSEL<1>. The PMOS transistor P502 operates as a switch which is turned on when the third selection signal SELB<3> is enabled to a logic low level, and transfers the third reference voltage VREF<3> as the first selection reference voltage VREFSEL<1>. The PMOS transistor P503 operates as a switch which is turned on when the fourth selection signal SELB<4> is enabled to a logic low level, and transfers the fourth reference voltage VREF<4> as the first selection reference voltage VREFSEL<1>.

Referring to FIG. 4, the second reference voltage selection section 51 includes a PMOS transistor P510, a PMOS transistor P511, a PMOS transistor P512, and a PMOS transistor P513. Specifically, the PMOS transistor P510 operates as a switch which is turned on when the first selection signal SELB<1> is enabled to a logic low level, and transfers the fifth reference voltage VREF<5> as a second selection reference voltage VREFSEL<2>. The PMOS transistor P511 operates as a switch which is turned on when the second selection signal SELB<2> is enabled to a logic low level, and transfers the sixth reference voltage VREF<6> as the second selection reference voltage VREFSEL<2>. The PMOS transistor P512 operates as a switch which is turned on when the third selection signal SELB<3> is enabled to a logic low level, and transfers the seventh reference voltage VREF<7> as the second selection reference voltage VREFSEL<2>. The PMOS transistor P513 operates as a switch which is turned on when the fourth selection signal SELB<4> is enabled to a logic low level, and transfers the eighth reference voltage VREF<8> as the second selection reference voltage VREFSEL<2>.

Referring to FIG. 4, the third reference voltage selection section 52 includes a PMOS transistor P520, a PMOS transistor P521, a PMOS transistor P522, and a PMOS transistor P523. Specifically, the PMOS transistor P520 operates as a switch which is turned on when the first selection signal SELB<1> is enabled to a logic low level, and transfers the ninth reference voltage VREF<9> as a third selection reference voltage VREFSEL<3>. The PMOS transistor P521 operates as a switch which is turned on when the second selection signal SELB<2> is enabled to a logic low level, and transfers the tenth reference voltage VREF<10> as the third selection reference voltage VREFSEL<3>. The PMOS transistor P522 operates as a switch which is turned on when the third selection signal SELB<3> is enabled to a logic low level, and transfers the eleventh reference voltage VREF<11> as the third selection reference voltage VREFSEL<3>. The PMOS transistor P523 operates as a switch which is turned on when the fourth selection signal SELB<4> is enabled to a logic low level, and transfers the twelfth reference voltage VREF<12> as the third selection reference voltage VREFSEL<3>.

Referring to FIG. 4, the fourth reference voltage selection section 53 includes a PMOS transistor P530, a PMOS transistor P531, a PMOS transistor P532, and a PMOS transistor P533. Specifically, the PMOS transistor P530 operates as a switch which is turned on when the first selection signal SELB<1> is enabled to a logic low level, and transfers the thirteenth reference voltage VREF<13> as a fourth selection reference voltage VREFSEL<4>. The PMOS transistor P531 operates as a switch which is turned on when the second selection signal SELB<2> is enabled to a logic low level, and transfers the fourteenth reference voltage VREF<14> as the fourth selection reference voltage VREFSEL<4>. The PMOS transistor P532 operates as a switch which is turned on when the third selection signal SELB<3> is enabled to a logic low level, and transfers the fifteenth reference voltage VREF<15> as the fourth selection reference voltage VREFSEL<4>. The PMOS transistor P533 operates as a switch which is turned on when the fourth selection signal SELB<4> is enabled to a logic low level, and transfers the sixteenth reference voltage VREF<16> as the fourth selection reference voltage VREFSEL<4>.

Returning to FIG. 2, the comparison unit 6 includes a first comparator 60, a second comparator 61, a third comparator 62, and a fourth comparator 63. Each of the comparators is operatively coupled to the sense voltage generation unit 2, the reference voltage selection unit 5 and the decoding unit 7. The first comparator 60 is configured to compare the level of the sense voltage VSENSE with the level of the first selection reference voltage VREFSEL<1>, and generate a first flag signal T1_FLAG which is enabled to a logic high level when the level of the sense voltage VSENSE is lower than the level of the first selection reference voltage VREFSEL<1>. The second comparator 61 is configured to generate a second flag signal T2_FLAG which is enabled to a logic high level when the level of the sense voltage VSENSE is lower than the level of the second selection reference voltage VREFSEL<2>. The third comparator 62 is configured to generate a third flag signal T3_FLAG which is enabled to a logic high level when the level of the sense voltage VSENSE is lower than the level of the third selection reference voltage VREFSEL<3>. The fourth comparator 63 is configured to generate a fourth flag signal T4_FLAG which is enabled to a logic high level when the level of the sense voltage VSENSE is lower than the level of the fourth selection reference voltage VREFSEL<4>. The comparison unit 6 configured as above compares the level of the sense voltage VSENSE with the levels of the first to fourth selection reference voltages VREFSEL<1:4>, and generates the first to fourth flag signals T1_FLAG to T4_FLAG. For example, when the inside temperature of the semiconductor integrated circuit is higher than the inside temperature corresponding to the second selection reference voltage VREFSEL<2> and lower than the inside temperature corresponding to the third selection reference voltage VREFSEL<2>, the sense voltage VSENSE is generated to be lower than the first and second selection reference voltages VREFSEL<1:2> and higher than the third and fourth selection reference voltages VREFSEL<3:4>. Therefore, the first flag signal T1_FLAG and the second flag signal T2_FLAG are enabled to a logic high level, and the third flag signal T3_FLAG and the fourth flag signal T4_FLAG are disabled to a logic low level.

The decoding unit 7 is configured to decode the first to fourth flag signals T1_FLAG to T4_FLAG to generate a temperature code TQN. The temperature code TQN may be implemented with a multi-bit signal according to embodiments.

The operation of the temperature sensor configured as above will be described below with reference to FIGS. 2 to 4.

Referring to FIG. 2, the sense voltage generation unit 2 senses the inside temperature of the semiconductor integrated circuit to generate the sense voltage VSENSE, and the reference voltage generation unit 3 generates the first to sixteenth reference voltages VREF<1:16> having levels corresponding to the inside temperature of the semiconductor integrated circuit.

Referring to FIG. 3, the selection signal generation unit 4 generates the first to fourth selection signals SELB<1:4> according to whether the operation mode is the test mode. That is, when the operation mode is not the test mode, the selection signal generation unit 4 outputs the first to fourth fuse selection signals FUSEL<1:4> as the first to fourth selection signals SELB<1:4>, wherein the first to fourth fuse selection signals FUSEL<1:4> are selectively enabled to a logic high level according to, and in response to, whether the first and second fuses (not shown) are cut or not. When the operation mode is the test mode, the selection signal generation unit 4 outputs the first to fourth test mode selection signals TMSEL<1:4> as the first to fourth selection signals SELB<1:4>, wherein the first to fourth test mode selection signals TMSEL<1:4> are selectively enabled to a logic high level whenever the test mode pulse TMP is inputted.

Referring to FIG. 4, the reference voltage selection unit 5 selectively outputs the first to fourth selection reference voltages VREFSEL<1:4> among the first to sixteenth reference voltages VREF<1:16> in response to the first to fourth selection signals SELB<1:4>.

Referring to FIG. 2, the comparison unit 6 compares the level of the sense voltage VSENSE with the levels of the first to fourth selection reference voltages VREFSEL<1:4> and generates the first to fourth flag signals T1_FLAG to T4_FLAG, and the decoding unit 7 decodes the first to fourth flag signals T1_FLAG to T4_FLAG and generates the temperature code TQN.

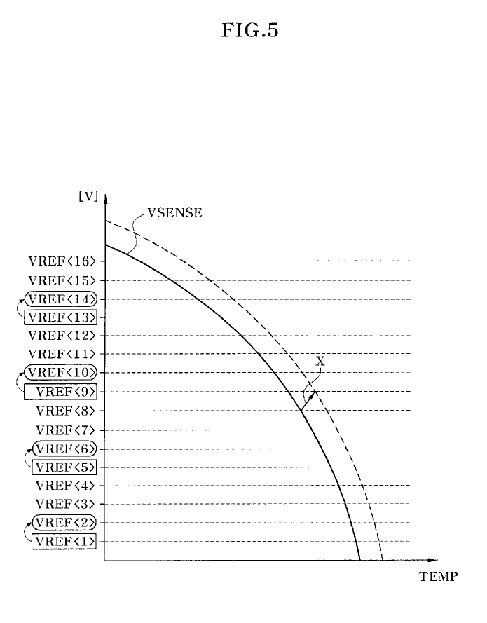

As illustrated in FIG. 5, when the level of the sense voltage VSENSE changes according to process variations as indicated by “X”, the levels of the first to fourth selection reference voltages VREFSEL<1:4> must change from the first reference voltage VREF<1>, the fifth reference voltage VREF<5>, the ninth reference voltage VREF<9>, and the thirteenth reference voltage VREF<13> to the second reference voltage VREF<2>, the sixth reference voltage VREF<6>, the tenth reference voltage VREF<10>, and the fourteenth reference voltage VREF<14>, respectively. This is because the first to fourth selection reference voltages VREFSEL<1:4> must also be changed in order to offset the level variation of the sense voltage VSENSE, that is, in order for the temperature sensor to perform the same operation even in the process variations.

Therefore, the temperature sensor according to this embodiment changes the levels of the first to fourth selection reference voltages VREFSEL<1:4> according to the cutting of the first and second fuses (not shown) or the number of the input of the test mode pulse TMP. That is, when the operation mode is not the test mode, only the first fuse (not shown) is cut. When the operation mode is the test mode, only the second selection signal SELB<2> is enabled to a logic low level by inputting the test mode pulse TMP one time. In this manner, the levels of the first to fourth selection reference voltages VREFSEL<1:4> are changed to the second reference voltage VREF<2>, the sixth reference voltage VREF<6>, the tenth reference voltage VREF<10>, and the fourteenth reference voltage VREF<14> by the second selection signal SELB<2> which is enabled to a logic low level.

As described above, when the level of the sense voltage VSENSE changes, the temperature sensor changes the levels of the first to fourth selection reference voltages VREFSEL<1:4> by cutting the fuses or inputting the test mode pulse TMP, thereby coping with the process variations without design modification. In other words, the temperature sensor thereby tracks changes in a voltage versus temperature characteristic of the sensing voltage, as shown in FIG. 5, which may change due to process variations.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A temperature sensor comprising:
a selection signal generation unit configured to generate first and second selection signals in response to a fuse cutting or an input of a test mode pulse in a test mode; and
a reference voltage selection unit, operatively coupled to the selection signal generation unit, configured to output a first reference voltage or a second reference voltage as a first selection reference voltage, and output a third reference voltage or a fourth reference voltage as a second selection reference voltage in response to the first and second selection signals.

2. The temperature sensor of claim 1, wherein the selection signal generation unit comprises:
a fuse selection signal generation section configured to generate first and second fuse selection signals according to the fuse cutting;
a test mode selection signal generation section configured to count a counting signal whenever the test mode pulse is inputted, and decode the counting signal to generate first and second test mode selection signals, when a test mode signal is enabled; and
a selective transfer section, operatively coupled to the fuse selection signal generation section and the test mode selection signal generation section, configured to output the first and second fuse selection signals or the first and second test mode selection signals as the first and second selection signals in response to the test mode signal.

3. The temperature sensor of claim 2, wherein the test mode selection signal generation section comprises:
a first counter configured to be driven when the test mode signal is enabled, and count a first counting signal in response to the test mode pulse;
a second counter, operatively coupled to the first counter, configured to be driven when the test mode signal is enabled, and count a second counting signal in response to the first counting signal; and
a test mode decoder, operatively coupled to the first counter and the second counter, configured to decode the first and second counting signals and generate the first and second test mode selection signals.

4. The temperature sensor of claim 2, wherein the selective transfer section comprises:
a first buffer configured to buffer the first and second fuse selection signals and transfer the buffered first and second fuse selection signals as the first and second selection signals, when the test mode signal is disabled; and
a second buffer configured to buffer the first and second test mode selection signals and transfer the buffered first and second test mode selection signals as the first and second selection signals, when the test mode signal is enabled.

5. The temperature sensor of claim 1, wherein the reference voltage selection unit comprises:
a first reference voltage selection section configured to output the first reference voltage or the second reference voltage as the first selection reference voltage in response to the first and second selection signals; and
a second reference voltage selection section configured to output the third reference voltage or the fourth reference voltage as the second selection reference voltage in response to the first and second selection signals.

6. The temperature sensor of claim 5, wherein the first reference voltage selection section comprises:
a first switch configured to be turned on in response to the first selection signal and transfer the first reference voltage as the first selection reference voltage; and
a second switch configured to be turned on in response to the second selection signal and transfer the second reference voltage as the first selection reference voltage.

7. The temperature sensor of claim 6, wherein the second reference voltage selection section comprises:
a third switch configured to be turned on in response to the first selection signal and transfer the third reference voltage as the second selection reference voltage; and
a fourth switch configured to be turned on in response to the second selection signal and transfer the fourth reference voltage as the second selection reference voltage.

8. A temperature sensor comprising:
a sense voltage generation unit configured to sense an inside temperature of a semiconductor integrated circuit and generate a sense voltage;
a selection signal generation unit configured to generate a selection signal in response to a fuse cutting or an input of a test mode pulse in a test mode;
a reference voltage selection unit, operatively coupled to the selection signal generation unit, configured to selectively output first and second selection reference voltages among a plurality of reference voltages in response to the selection signal;
a first comparator, operatively coupled to the sense voltage generation unit and the reference voltage selection unit, configured to compare the first selection reference voltage with the sense voltage, and generate a first flag signal; and
a second comparator, operatively coupled to the sense voltage generation unit and the reference voltage selection unit, configured to compare the second selection reference voltage with the sense voltage, and generate a second flag signal.

9. The temperature sensor of claim 8, wherein the selection signal generation unit comprises:
a fuse selection signal generation section configured to generate a fuse selection signal according to the fuse cutting;
a test mode selection signal generation section configured to count a counting signal whenever the test mode pulse is inputted, and decode the counting signal to generate a test mode selection signal, when a test mode signal is enabled; and
a selective transfer section, operatively coupled to the fuse selection signal generation section and the test mode selection signal generation section, configured to output the fuse selection signal or the test mode selection signal as the selection signal in response to the test mode signal.

10. The temperature sensor of claim 9, wherein the test mode selection signal generation section comprises:
a first counter configured to be driven when the test mode signal is enabled, and count a first counting signal in response to the test mode pulse;
a second counter, operatively coupled to the first counter, configured to be driven when the test mode signal is enabled, and count a second counting signal in response to the first counting signal; and
a test mode decoder, operatively coupled to the first counter and the second counter, configured to decode the first and second counting signals and generate the test mode selection signal.

11. The temperature sensor of claim 9, wherein the selective transfer section comprises:
a first buffer configured to buffer the fuse selection signal and transfer the buffered fuse selection signal as the selection signal, when the test mode signal is disabled; and
a second buffer configured to buffer the test mode selection signal and transfer the buffered test mode selection signal as the selection signal, when the test mode signal is enabled.

12. The temperature sensor of claim 8, wherein the reference voltage selection unit comprises:
a first reference voltage selection section configured to output a first reference voltage or a second reference voltage as the first selection reference voltage in response to a first and second selection signal; and
a second reference voltage selection section configured to output a third reference voltage or a fourth reference voltage as the second selection reference voltage in response to the first and second selection signals.

13. The temperature sensor of claim 12, wherein the first reference voltage selection section comprises:
a first switch configured to be turned on in response to the first selection signal and transfer the first reference voltage as the first selection reference voltage; and
a second switch configured to be turned on in response to the second selection signal and transfer the second reference voltage as the first selection reference voltage.

14. The temperature sensor of claim 13, wherein the second reference voltage selection section comprises:
a third switch configured to be turned on in response to the first selection signal and transfer the third reference voltage as the second selection reference voltage; and
a fourth switch configured to be turned on in response to the second selection signal and transfer the fourth reference voltage as the second selection reference voltage.

15. The temperature sensor of claim 8, wherein the first comparison unit is further configured to generate the first flag signal when the sense voltage is lower than the first selection reference voltage.

16. The temperature sensor of claim 8, wherein the second comparison unit is configured to generate the second flag signal when the sense voltage is lower than the second selection reference voltage.

17. The temperature sensor of claim 8, further comprising a decoding unit, operatively coupled to the first comparator and the second comparator, configured to decode the first and second flag signals and generate a temperature code.

18. A temperature sensor comprising:
a reference voltage selection unit; and
a comparison unit, operatively coupled to the reference voltage selection unit, operative to receive a plurality of reference voltages from the reference voltage selection unit and provide a plurality of comparator outputs comparing each reference voltage of the plurality of reference voltages with a sense voltage corresponding to an internal temperature of an integrated circuit, wherein the temperature sensor thereby tracks changes in a voltage versus temperature characteristic of the sensing voltage.
